(19) United States
(12) Patent Application Publication
(10) Pub. No.: US 2018/0027645 A1
(43) Pub. Date: Jan. 25, 2018

(54) SUBSTRATE UNIT

(71) Applicants: AutoNetworks Technologies, Ltd., Yokkaichi, Mie (JP); Sumitomo Wiring Systems, Ltd., Yokkaichi, Mie (JP); Sumitomo Electric Industries, Ltd., Osaka-shi, Osaka (JP)

(72) Inventors: Hideaki Tahara, Yokkaichi, Mie (JP); Kazuyoshi Ohara, Yokkaichi, Mie (JP); Munsoku O, Yokkaichi, Mie (JP); Arinobu Nakamura, Yokkaichi, Mie (JP)

(21) Appl. No.: 15/549,312

(22) PCT Filed: Jan. 29, 2016
(86) PCT No.: PCT/JP2016/052577

§ 371 Date: Aug. 7, 2017

(30) Foreign Application Priority Data
Feb. 19, 2015 (JP) 2015-030796

(51) Int. Cl. H05K 1/02; H05K 1/18; H01L 23/36

(52) U.S. Cl. CPC H05K 1/0203; H01L 23/36; H05K 1/183

(57) ABSTRACT

Provided is a substrate unit that has an excellent heat dissipation capability. A substrate unit includes: a substrate having a conductive pattern formed on one surface thereof, the substrate being provided with an opening; a conductive member that includes a main portion that is fixed to the other surface of the substrate, and to which at least one terminal of an electronic component is electrically connected via the opening that is formed in the substrate; and a heat dissipation member with which an extension portion that extends from the main portion of the conductive member is in contact.

### CROSS-REFERENCE TO RELATED APPLICATIONS

This application is the U.S. national stage of PCT/JP2016/052577 filed Jan. 29, 2016, which claims priority of Japanese Patent Application No. JP 2015-030796 filed Feb. 19, 2015.

### TECHNICAL FIELD

The present invention relates to a substrate unit that includes a substrate and a conductive member.

### BACKGROUND

There are well-known substrate units in which a conductive member (also referred to as a bus bar, for example) that is part of a circuit that allows a relatively large current to pass therethrough is fixed to a substrate on which a conductive pattern that is part of a circuit that allows a relatively small current to pass therethrough is formed (for example, JP 2003-164040A). The substrate units include a heat dissipation member that is fixed to one side of the conductive member (the side opposite the substrate side). It is also possible to conceive of a substrate unit that is not provided with such a heat dissipation member, and in which the conductive member per se is configured to serve as a member for dissipating heat.

Conventional substrate units such as the substrate unit disclosed in JP 2003-164040A are configured to perform heat dissipation from only one side, and there are cases in which a sufficient heat dissipation capability cannot be secured. If the heat dissipation member is enlarged in order to secure its heat dissipation capability, the unit accordingly becomes larger.

A problem to be solved by the present invention is to provide a substrate unit that has an excellent heat dissipation capability.

### SUMMARY OF INVENTION

In order to solve the above-described program, a substrate unit according to one aspect of the present invention includes: a substrate that has one surface on which a conductive pattern is formed, and that is provided with an opening; a conductive member that includes a main portion that is fixed to the other surface of the substrate, and to which at least one terminal of an electronic component is electrically connected via the opening that is formed in the substrate; and a heat dissipation member with which an extension portion that extends from the main portion of the conductive member is in contact.

It is preferable that the extension portion is in contact with the heat dissipation member with an insulative material being interposed therebetween.

It is preferable that the extension portion of the conductive member is arranged passing outside the substrate.

It is preferable that the extension portion of the conductive member is arranged penetrating through the substrate.

If this is the case, it is preferable that the extension portion of the conductive member, which is arranged penetrating through the substrate, is fixed to the substrate.

It is preferable that the heat dissipation member is provided on the side of the one surface of the substrate.

In the substrate unit according to this aspect of the present invention, the generated heat is transferred to the heat dissipation member via the extension portion of the conductive member, and is dissipated from the heat dissipation member. In other words, the substrate unit is configured such that heat is not only directly or indirectly dissipated (via another heat dissipation member) from the main portion of the conductive member, but is also dissipated from the extension portion of the conductive member via the heat dissipation member. Therefore, heat dissipation efficiency is higher than that of the prior art. Also, since it is possible to secure sufficient heat dissipation efficiency, the unit can be small.

If the unit is configured such that the extension portion is in contact with the heat dissipation member with the insulative material being interposed therebetween, a short circuit via the heat dissipation member can be prevented from occurring.

If the extension portion of the conductive member is arranged passing outside the substrate, there is no need to provide the substrate with a hole or the like that allows the extension portion to pass therethrough.

If the extension portion of the conductive member is arranged penetrating through the substrate, the unit can be small. In this case, it is possible to more firmly join the substrate and the conductive member to each other by fixing the extension portion to the substrate. Also, if the extension portion is fixed to the substrate, the extension portion is restricted from moving, and therefore it is possible to reduce a stress that is applied to the connecting portion between the extension portion and the heat dissipation member.

If the heat dissipation member is located on the side of the one surface of the substrate, the heat dissipation member and the conductive member face each other with the substrate being interposed therebetween. Therefore, such a configuration allows heat to be dissipated from both sides, namely one surface side and the other surface side of the substrate, and a high heat dissipation efficiency can be achieved. If this is the case, if a configuration in which the heat dissipation member is not in contact with the electronic component is employed, an increase in a stress that is applied to the electronic component can be suppressed (compared to a configuration in which the heat dissipation member is in contact with the electronic component).

### BRIEF DESCRIPTION OF DRAWINGS

FIG. 1 schematically shows a cross section of a substrate unit according to an embodiment of the present invention.

FIG. 2 is an external perspective view of a set consisting of a substrate and a conductive member.

FIG. 3 is an enlarged view of a portion (including a substrate and a conductive member that is fixed to the substrate) of the substrate unit, on which an electronic component (that has at least one terminal that is electrically connected to the conductive member) is mounted.

FIG. 4 is a cross-sectional view of the portion (including the substrate and the conductive member that is fixed thereto) of the substrate unit, on which the electronic component (that has at least one terminal that is electrically connected to the conductive member) is mounted, and is a cross-sectional view along a plane that passes through a drain terminal and a source terminal.

FIG. 5 schematically shows a cross section of a substrate unit in which a first heat dissipation member constitutes not only a lower wall but also a side wall.

FIG. 6 schematically shows a cross section of a substrate unit in which a second heat dissipation member constitutes not only an upper wall but also a side wall.

FIG. 7 shows a step of manufacturing a substrate unit, and illustrates a step of joining a substrate to a conductive member to obtain a set consisting of a substrate and a conductive member.

FIG. 8 shows steps of manufacturing a substrate unit, and illustrates steps that are performed after a set consisting of a substrate and a conductive member has been obtained.

FIG. 9 schematically shows a cross section of a substrate unit in which an extension portion intersects a substrate.

FIG. 10 schematically shows a cross section of a substrate unit that has a configuration in which an extension portion is in direct or indirect contact with a portion of a heat dissipation member, the portion constituting a side wall.

### DETAILED DESCRIPTION OF THE PREFERRED EMBODIMENTS

The following describes embodiments of the present invention in detail with reference to the drawings. In the following description, “in-plane direction” refers to an in-plane direction of a substrate 10 and a conductive member 20, and “height direction” (vertical direction) refers to a direction that is orthogonal to the in-plane direction (the side of the substrate 10 that is opposite the side to which the conductive member 20 is fixed is regarded as the upper side), unless otherwise specified. Note that these directions do not limit the orientation in which a substrate unit 1 is installed.

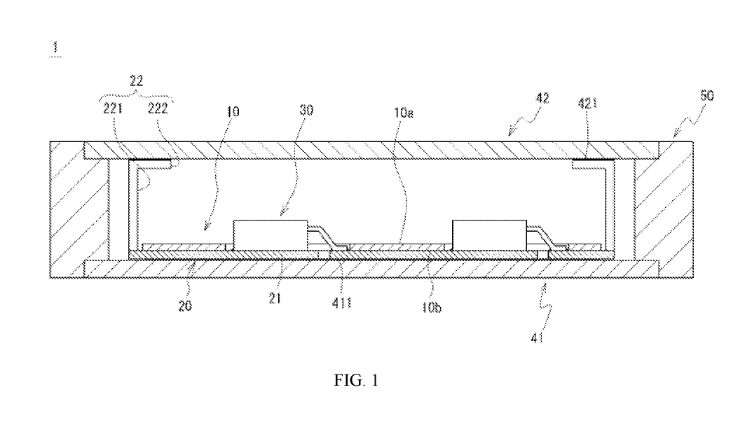

The substrate unit 1 according to an embodiment of the present invention shown in FIG. 1 includes a substrate 10, a conductive member 20, electronic components 30, a first heat dissipation member 41, and a second heat dissipation member 42. A conductive pattern is formed on one surface 10a (an upper surface) of the substrate 10. A conducting path that is constituted by the conductive pattern is a conducting path (part of the circuitry) for control signals, and a current flowing through this conducting path is smaller than a current flowing through a conducting path (part of the circuitry) that is constituted by the conductive member 20.

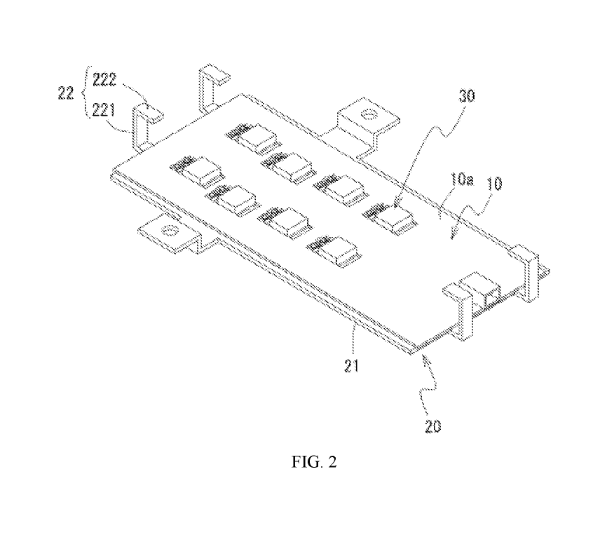

The conductive member 20 includes a main portion 21 that is fixed to another surface 10b (a lower surface) of the substrate 10 and extends in the in-plane direction, and an extension portion 22 that extends from the main portion 21. The conductive member 20 is formed in a predetermined shape through stamping or the like. The main portion 21 of the conductive member 20 constitutes a conducting path for power supply, which is a portion where a current that is relatively large (larger than a current flowing through the conducting path that is constituted by the conductive pattern) flows. Note that, although specific configurations of conducting paths are not described or illustrated in detail (see JP 2003-164040A, for example), the main portion 21 of the conductive member 20 includes a plurality of portions that constitute conducting paths. The portions are independent of each other so as not to cause a short circuit, and are integrated into one piece by being fixed to the substrate 10. Before being fixed to the substrate 10, the plurality of portions are continuous via extra portions. After the plurality of portions have been fixed to the substrate 10, the extra portions are cut away, and thus each portion is brought into an independent state (a state in which each portion is not in direct contact with any other portions). The conductive member 20 (the main portion 21) is also referred to as a bus bar (a bus bar plate) or the like. The main portion 21 of the conductive member 20 is fixed to the other surface 10b of the substrate 10, using an insulative adhesive or adhesive sheet, for example. Thus, the substrate 10 and the conductive member 20 are integrated into one piece, and a set consisting of the substrate 10 and the conductive member 20 as shown in FIG. 2 can be obtained. It can be said that the substrate unit 1 according to the present embodiment is a substrate unit in which the set consisting of the substrate 10 and the conductive member 20 is housed in a space that is defined by a first heat dissipation member 41, a second heat dissipation member 42, and a casing member 50, which will be described below in detail.

The extension portion 22 of the conductive member 20 is a portion that is formed standing upright on the main portion 21. The extension portion 22 includes a portion (a base end portion 221) that extends upward from the main portion 21, and a portion (a top end portion 222) that bends from a top end (an upper end) of the base end portion 221 and extends in the in-plane direction. The conductive member 20 according to the present embodiment includes a plurality of extension portions 22. Each extension portion 22 is integrated into one piece with one of the above-described independent portions of the main portion 21.

The first heat dissipation member 41 is fixed to the lower side (the side that is opposite the substrate 10 side) of the main portion 21 of the conductive member 20. If the first heat dissipation member 41 is made of a conductive material, it is preferable that the conductive member 20 and the first heat dissipation member 41 are insulated from each other. Specifically, it is preferable that the main portion 21 of the conductive member 20 and the first heat dissipation member 41 are joined to each other with an insulative material 411 that has a high thermal conductivity being interposed therebetween. It is also possible to employ a configuration in which no first heat dissipation member 41 is provided, and at least a portion of the conductive member 20 is exposed to the outside so that the conductive member 20 itself achieves a heat dissipation function (so that the lower surface of the main portion 21 of the conductive member 20 serves as a heat dissipation surface). The shape and so on of the first heat dissipation member 41 may be modified as appropriate. In order to improve heat dissipation efficiency, it is possible to provide fins or the like outside the first heat dissipation member 41.

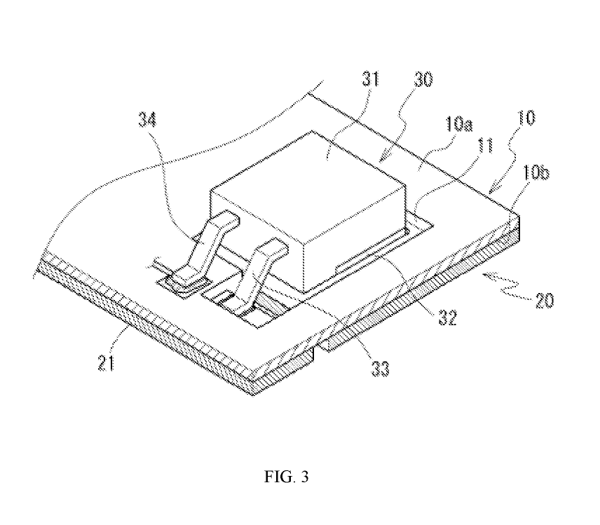

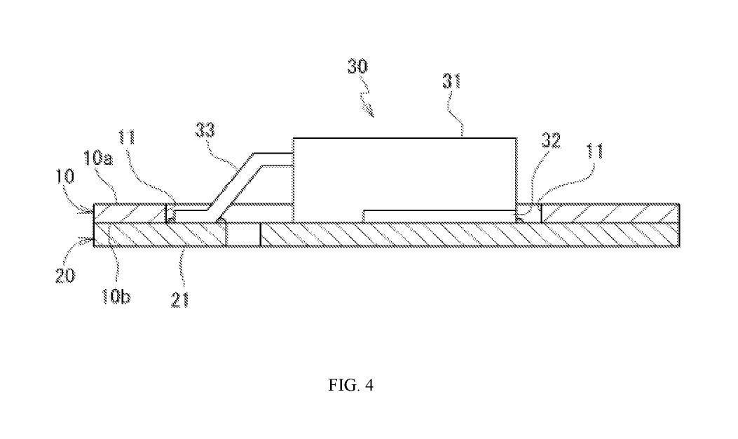

The electronic components 30 are devices that are mounted on the set consisting of the substrate 10 and the conductive member 20, and include a device body 31 and a terminal portion. A plurality of electronic components 30 are mounted on the set consisting of the substrate 10 and the conductive member 20. As shown in FIGS. 3 and 4, at least one terminal of a particular electronic component 30 is electrically and physically connected to the main portion 21 of the conductive member 20 via a conductive material such as solder, through an opening 11 that is formed in the substrate 10. A transistor (an FET) is an example of an electronic component that has at least one terminal that is electrically connected to the main portion 21 of the conductive member 20. A drain terminal 32 and a source terminal 33 of the transistor are electrically connected to the main portion 21 of the conductive member 20 through the opening 11, and a gate terminal 34 of the same is electrically connected to a conductive pattern (a land) of the substrate 10. Note that an independent portion of the main portion 21 to which the drain terminal 32 is connected and an independent portion of the main portion 21 to which the source terminal 33 is connected are different. In this way, at least one terminal of the electronic components 30 that are mounted on the set consisting of the substrate 10 and the conductive member 20 is electrically connected to the conductive member 20.

Note that there may also be an electronic component 30 all terminals of which are electrically connected directly to the conductive pattern that is formed on the substrate 10 (there may also be an electronic component that has at least one terminal that is not electrically connected directly to the conductive member 20). The specific configuration of the conductive member 20 may be modified as appropriate as long as the conductive member 20 is fixed to the substrate 10, and constitutes a conducting path that is different from the conducting path that is constituted by the conductive pattern that is formed on the substrate 10.

The second heat dissipation member 42 (corresponding to a heat dissipation member of the present invention) is located on the one surface 10a side (the upper side) of the substrate 10. According to the present embodiment, the substrate 10, the main portion 21 of the conductive member 20, the first heat dissipation member 41, and the second heat dissipation member 42 are arranged parallel with each other. The substrate 10 is located between the first heat dissipation member 41 and the main portion 21 of the conductive member 20 on the one hand, and the second heat dissipation member 42 on the other hand, so that the first heat dissipation member 41 and the main portion 21 of the conductive member 20 face the second heat dissipation member 42. The top end portions 222 of the extension portions 22 of the above-described conductive member 20 are in direct or indirect contact with the second heat dissipation member 42 (both “direct contact” and “indirect contact” correspond to “contact” according to the present invention). According to the present embodiment, the top end portions 222 of the extension portions 22 and the second heat dissipation member 42 are joined to each other with an insulative material 421 that has a high thermal conductivity being interposed therebetween, in order to secure insulation between the extension portions 22 (the main portion 21 of the conductive member 20) and the second heat dissipation member 42. In other words, the extension portions 22 and the second heat dissipation member 42 are in indirect contact with each other with the insulative material 421 that has a high thermal conductivity being interposed therebetween. The shape and so on of the second heat dissipation member 42 may be modified as appropriate. In order to improve heat dissipation efficiency, it is possible to provide fins or the like outside the second heat dissipation member 42.

The second heat dissipation member 42 faces the one surface 10a of the substrate 10 at a predetermined distance therebetween, and this distance is longer than the height of the highest electronic component 30 (in the vertical direction) of the electronic components 30 mounted on the set consisting of the substrate 10 and the conductive member 20. Therefore, the second heat dissipation member 42 is not in contact with any of the electronic components 30.

Also, the extension portions 22 according to the present embodiment are arranged passing outside the substrate 10 (outside the outer edge of the substrate 10). In other words, the extension portions 22 do not intersect the one surface 10a of the substrate 10. Therefore, there is no short circuit between the extension portions 22 and the circuitry that is on the substrate 10.

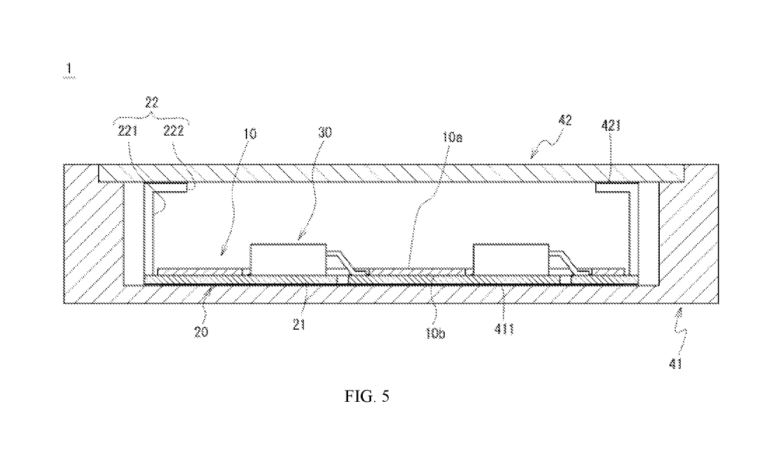

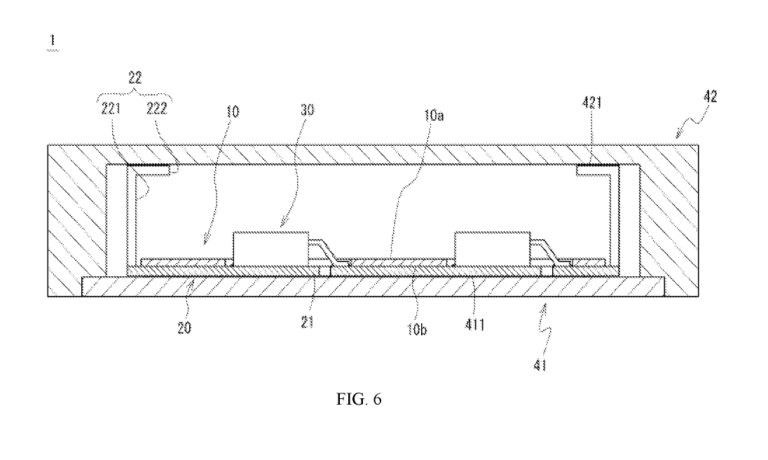

The first heat dissipation member 41 and the second heat dissipation member 42 are integrated into one piece by the casing member 50 that constitutes a side wall of the unit. In other words, the substrate unit 1 according to the present embodiment is configured such that at least a portion of a lower wall is constituted by the first heat dissipation member 41, at least a portion of an upper wall is constituted by the second heat dissipation member 42, and the side wall is constituted by the casing member 50. However, as shown in FIG. 5, it is also possible to employ a configuration in which the first heat dissipation member 41 constitutes not only the lower wall but also the side wall. Also, as shown in FIG. 6, it is possible to employ a configuration in which the second heat dissipation member 42 constitutes not only the upper wall but also the side wall. In other words, it is possible to employ a configuration in which no casing member 50 is used.

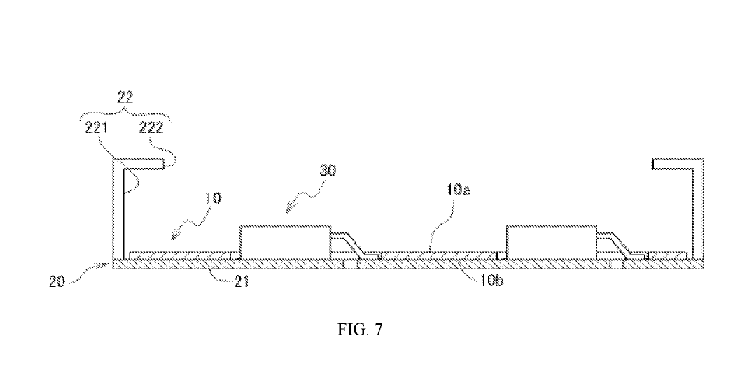

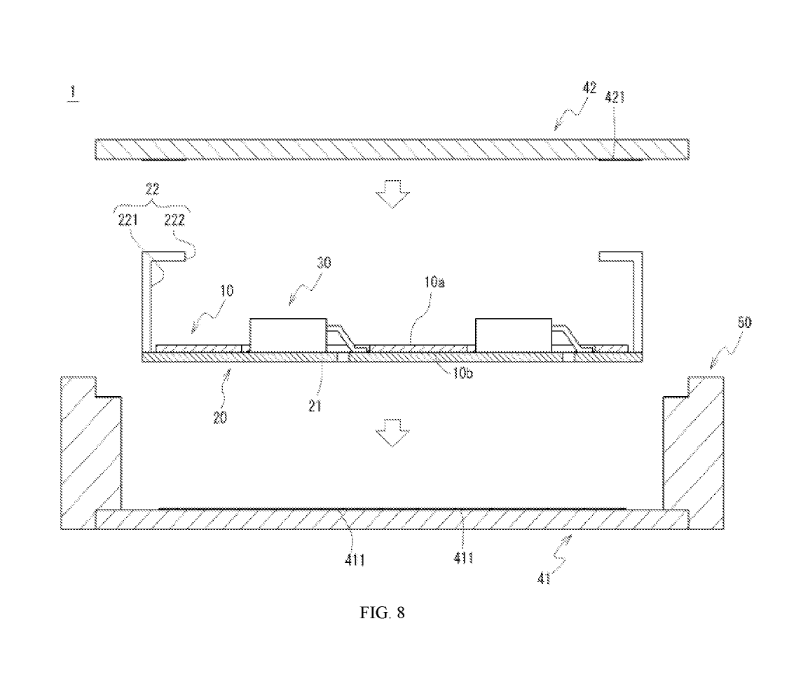

The substrate unit 1 according to the present embodiment can be manufactured as follows (see FIG. 7 for step (1), and see FIG. 8 for steps (2) to (4)).

### Step (1)

The set consisting of the substrate 10 and the conductive member 20, in which the electronic components 30 are mounted on the substrate 10 and the conductive member 20, is obtained (the timing of, and the method for mounting the electronic components 30 can be freely selected). Note that the extension portions 22 may also be bent (the top end portions 222 may also be formed) after the substrate 10 and the conductive member 20 are joined to each other, and it is also possible that the extension portions 22 are bent in advance and then the substrate 10 and the conductive member 20 are joined to each other (any method that makes the task of joining easier can be selected).

### Step (2)

The first heat dissipation member 41 is fixed to the casing member 50. Thus, a set consisting of the first heat dissipation member 41 and the casing member 50 is obtained.

### Step (3)

The set consisting of the substrate 10 and the conductive member 20 is attached to the set consisting of the first heat dissipation member 41 and the casing member 50. In other words, the conductive member 20 is joined to the first heat dissipation member 41 with the insulative material 411, which has a high thermal conductivity, being interposed therebetween. Thus, the first heat dissipation member 41 is joined, and a set consisting of the substrate 10, the conductive member 20, the first heat dissipation member 41, and the casing member 50 is obtained.

### Step (4)

The second heat dissipation member 42 is attached to the set consisting of the substrate 10, the conductive member 20, the first heat dissipation member 41, and the casing member 50. In other words, the second heat dissipation member 42 is fixed to the casing member 50, and also, the extension portions 22 of the conductive member 20 are joined to the second heat dissipation member 42 with the insulative material 421, which has a high thermal conductivity, being interposed therebetween. Thus, the substrate unit 1 is obtained.

Note that the order in which steps (2) and (3) above are performed may be reversed.

As described above, in the substrate unit 1 according to the present embodiment, the extension portions 22 of the conductive member 20 are in contact with the second heat dissipation member 42, and therefore at least a portion of: the heat generated by those electronic components 30 that are driven (in particular, the heat generated by an electronic component 30 that generates a large amount of heat, such as a power semiconductor), and the heat generated by the substrate 10 and the conductive member 20 due to a current being supplied to the circuitry, is transferred to the second heat dissipation member 42 via the extension portions 22 of the conductive member 20, and is dissipated from the second heat dissipation member 42. In other words, in addition to a path via the first heat dissipation member 41, a path via the second heat dissipation member 42 is added to the heat dissipation path, and therefore a heat dissipation efficiency that is higher than that of the prior art is achieved. Also, a path that transfers heat to the second heat dissipation member 42 is constituted by the conductive member 20 (the extension portions 22), and therefore there is no need to mount another member for transferring heat to the second heat dissipation member 42, and it is possible to reduce costs.

In particular, the substrate unit 1 according to the present embodiment is usually installed such that the one surface 10a of the substrate 10 faces upward. In this case, the second heat dissipation member 42 is located on the upper side of the unit. In other words, the amount of heat that is dissipated from the upper side of the unit is greater than that of the prior art, and the heat dissipation efficiency of the entire unit is higher than that of the prior art.

Also, in the substrate unit 1 according to the present embodiment, the second heat dissipation member 42 is not in contact with the electronic components 30. Therefore, an increase in stress that is applied to the electronic components 30 is suppressed compared to configurations in which the second heat dissipation member 42 is in contact with the electronic components 30.

Also, the extension portions 22 of the conductive member 20 according to the present embodiment pass outside the substrate 10. Therefore, there is no need to provide the substrate 10 with holes or the like that allow the extension portions 22 to pass therethrough.

Although embodiments of the present invention have been described above in detail, the present invention is not limited to the above-described embodiments in any manner, and may be variously modified within the spirit of the present invention.

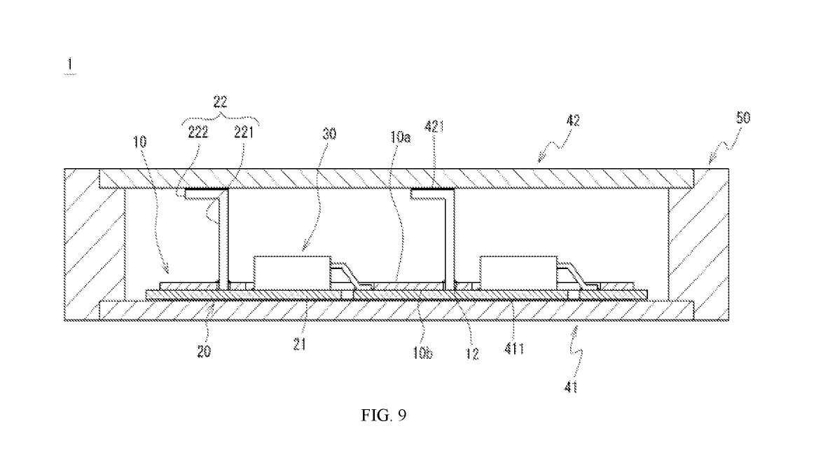

For example, in the embodiments above, the extension portions 22 of the conductive member 20 have been described as passing outside the substrate 10. However, as shown in FIG. 9, the extension portions 22 may also intersect the substrate 10. The substrate 10 is provided with the same number of through holes 12 (which may be slits) as there are extension portions 22, and the extension portions 22 are passed through the through holes 12. If it is desired that the through holes 12 are as small as possible, the extension portions 22 are kept straight until the substrate 10 and the conductive member 20 are integrated into one piece, and top side portions of the extension portions 22 are bent after the extension portions 22 have been passed through the through holes 12. Through these operations, it is possible to set the size of the through holes 12 to be slightly larger than the thickness of the extension portions 22 (slightly larger than the outer edges of the extension portions 22).

The extension portions 22 intersect the substrate 10, and therefore the extension portions 22 can be fixed to the substrate 10. Specifically, as with the electronic components 30, the extension portions 22 can be fixed to the substrate 10 through soldering or the like. In this case, the electronic components 30 and the extension portions 22 are not electrically connected via the conductive pattern formed on the substrate 10. The extension portions 22 can be fixed in the same step as the mounting the electronic components 30 (e.g. the step of mounting through reflow soldering).

The unit can be small if the extension portions 22 of the conductive member 20 penetrate through the substrate 10 in this way. Furthermore, if the unit is configured such that the extension portions 22 that penetrate through the substrate 10 are fixed to the substrate 10, the substrate 10 and the conductive member 20 can be more firmly joined to each other. Also, the extension portions 22 are restricted from moving by being fixed to the substrate 10, and therefore a stress that is applied to the connecting portion between the extension portions 22 and the second heat dissipation member 42 can be reduced.

Also, in the embodiments above, the unit has been described as being provided with the first heat dissipation member 41 that is fixed to the lower side of the main portion 21 of the conductive member 20. However, as described above, it is possible to employ a configuration in which no first heat dissipation member 41 is provided, and in which the main portion 21 of the conductive member 20 itself functions as a member for improving heat dissipation performance. Specifically, if a configuration in which at least a portion of the main portion 21 of the conductive member 20 is exposed from the lower side of the unit is employed, at least a portion of heat that has been generated is dissipated from the lower side of the unit via the conductive member 20. Even in this case, at least a portion of heat that has been generated is transferred from the extension portions 22 to the second heat dissipation member 42, and is dissipated from the upper side of the unit via the second heat dissipation member 42.

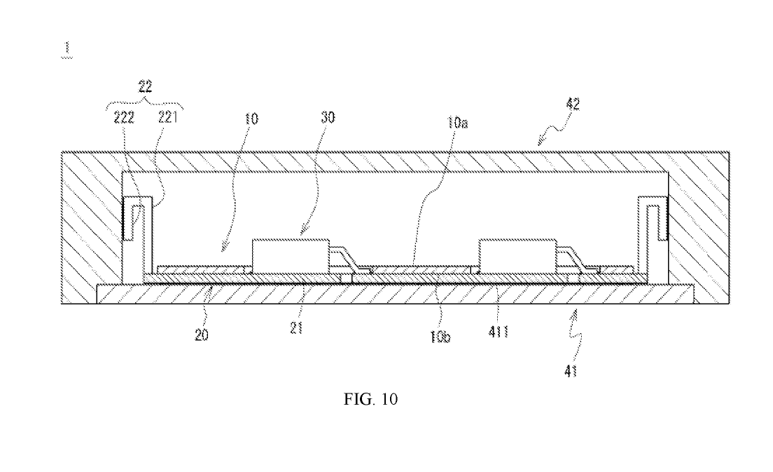

In the embodiments above, the extension portions 22 have been described as being in contact with the second heat dissipation member 42 that is provided on the one surface 10a side of the substrate 10 (the second heat dissipation member 42 that constitutes at least a portion of the upper wall of the unit). However, if a configuration in which the side wall is constituted by the heat dissipation member as shown in FIGS. 5 and 6 is employed, it is possible to employ a configuration in which the extension portions 22 are in direct or indirect contact with the portion of the heat dissipation member that constitutes the side wall as shown in FIG. 10. Also, it is possible to employ a configuration that includes: an extension portion 22 that is in direct or indirect contact with the portion that constitutes the upper wall; and an extension portion 22 that is in direct or indirect contact with the portion that constitutes the side wall. In other words, it is possible to employ a configuration in which: the first heat dissipation member 41 that is fixed to the main portion 21 of the conductive member 20; and the extension portions 22 for improving heat dissipation performance via a path that is different from the heat dissipation path (in the heat dissipation direction) of the main portion 21 per se are used.

In the embodiments above, the extension portions 22 of the conductive member 20 and the second heat dissipation member 42 have been described as being joined to each other with the insulative material 421 that has a high thermal conductivity being interposed therebetween (in indirect contact with each other with an insulative material that has a high thermal conductivity being interposed therebetween). However, in cases where such insulation does not need to be secured (e.g. in cases where only one extension portion 22 is formed on the conductive member 20), it is also possible to employ a configuration in which the top end portion 222 of the extension portion 22 is in direct contact with the second heat dissipation member 42 (a configuration in which the aforementioned insulation is not secured).

1. A substrate unit comprising:
a substrate having a conductive pattern formed on one surface thereof, the substrate being provided with an opening;
a conductive member that includes a main portion that is fixed to the other surface of the substrate, and to which at least one terminal of an electronic component is electrically connected via the opening that is provided in the substrate; and
a heat dissipation member with which an extension portion that extends from the main portion of the conductive member is in contact.

2. The substrate unit according to claim 1,
wherein the extension portion is in contact with the heat dissipation member with an insulative material being interposed therebetween.

3. The substrate unit according to claim 1,
wherein the extension portion of the conductive member passes outside the substrate.

4. The substrate unit according to claim 1,
wherein the extension portion of the conductive member penetrates through the substrate.

5. The substrate unit according to claim 4,
wherein the extension portion of the conductive member, which penetrates through the substrate, is fixed to the substrate.

6. The substrate unit according to claim 1,
wherein the heat dissipation member is arranged on the side of the one surface of the substrate.

7. The substrate unit according to claim 6,
wherein the heat dissipation member is not in contact with the electronic component.

8. The substrate unit according to claim 2,
wherein the extension portion of the conductive member passes outside the substrate.

9. The substrate unit according to claim 2,
wherein the extension portion of the conductive member penetrates through the substrate.

10. The substrate unit according to claim 9,
wherein the extension portion of the conductive member, which penetrates through the substrate, is fixed to the substrate.

11. The substrate unit according claim 2,
wherein the heat dissipation member is arranged on the side of the one surface of the substrate.

12. The substrate unit according claim 3,
wherein the heat dissipation member is arranged on the side of the one surface of the substrate.

13. The substrate unit according claim 4,
wherein the heat dissipation member is arranged on the side of the one surface of the substrate.

14. The substrate unit according claim 5,
wherein the heat dissipation member is arranged on the side of the one surface of the substrate.
